(19) United States
(12) Patent Application Publication
(10) Pub. No.: US 2025/0038010 A1
(43) Pub. Date: Jan. 30, 2025

(54) VIAS INCLUDING AN ELECTROPLATED LAYER AND METHODS FOR FABRICATING THE VIAS

(71) Applicant: CORNING INCORPORATED, Corning, NY (US)

(72) Inventors: Bomi Kim, Cheonan city (KR); Joo Sok Kim, Yongin-si (KR); Hyung Soo Moon, Gangnam-gu (KR); Seong-ho Seok, Seoul (KR)

(21) Appl. No.: 18/710,783

(22) PCT Filed: Nov. 15, 2022
(86) PCT No.: PCT/US2022/049926

§ 371 Date: May 16, 2024

(30) Foreign Application Priority Data
Nov. 29, 2021 (KR) 10-2021-0167315

(51) Int. Cl. H01L 21/48; H01L 21/02; H01L 21/768; H01L 23/15; H01L 23/48

(52) U.S. Cl. CPC H01L 21/486; H01L 21/02304; H01L 21/76804; H01L 21/76873; H01L 21/76898; H01L 23/15; H01L 23/481

(57) ABSTRACT

A via includes a substrate, a seed layer, and an electroplated layer. The substrate includes a first surface and a second surface opposite to the first surface. The substrate includes a tapered through-hole extending from the first surface to the second surface. The seed layer includes copper contacting the substrate on sidewalls of the tapered through-hole. The electroplated layer includes copper contacting the seed layer.

### BACKGROUND

### Cross-Reference to Related Applications

This application claims the benefit of priority under 35 U.S.C. § 119 of Korean Patent Application Serial No.: 10-2021-0167315, filed on Nov. 29, 2021, the content of which is relied upon and incorporated herein by reference in its entirety.

### Field

The present disclosure relates generally to vias. More particularly, it relates to tapered vias including an electroplated layer.

### Technical Background

The desire for miniaturization and improved electrical performance has resulted in the emergence of 3D and 2.5D chip stacking architectures, which use vertical electrical interconnects. These vertical interconnects may be fabricated by forming holes through substrates and forming a conductive path within each hole, resulting in short interconnects having a high electrical performance. Through-silicon via (TSV) has been the most prominent vertical interconnect. The challenges associated with 3D stacking of chips, however, has shifted attention to 2.5D chip stacking architectures, as 2.5D chip stacking architectures are less expensive and present fewer integration challenges. The 2.5D chip stacking architectures may be realized by the use of non-active substrates (having no integrated front end devices) with vertical interconnects, which are often referred to as interposers. Interposer substrates may be made of silicon or glass.

Glass interposers with through-glass vias (TGV) are attractive due to the many advantages of glass over silicon that includes lower cost, tunable coefficient of thermal expansion (CTE), and superior high frequency performance. The formation of TGVs, however, presents thermo-mechanical challenges that arise due to the CTE mismatch between the glass matrix (e.g., about 0.6 ppm/° C. for fused silica) and the metal fill (e.g., copper is about 16.7 ppm/° C.). This CTE difference leads to high stress buildup during thermal cycling that results in different failure modes, such as cracks in the substrate, via voiding, sidewall delamination, etc.

### SUMMARY

Some embodiments of the present disclosure relate to a via. The via includes a substrate, a seed layer, and an electroplated layer. The substrate includes a first surface and a second surface opposite to the first surface. The substrate includes a tapered through-hole extending from the first surface to the second surface. The seed layer includes copper contacting the substrate on sidewalls of the tapered through-hole. The electroplated layer includes copper contacting the seed layer.

Yet other embodiments of the present disclosure relate to a via. The via includes a substrate, a seed layer, an electroplated layer, and a polymer. The substrate includes a first surface and a second surface opposite to the first surface. The substrate includes a tapered through-hole extending from the first surface to the second surface. The seed layer includes copper contacting the substrate on sidewalls of the tapered through-hole. The electroplated layer includes copper contacting the seed layer. The polymer contacts the electroplated layer and fills the through-hole.

Yet other embodiments of the present disclosure relate to a method for fabricating a via. The method includes forming a tapered through-hole through a substrate from a first surface of the substrate to a second surface of the substrate opposite to the first surface. The method includes applying a seed layer comprising copper on sidewalls of the tapered through-hole. The method includes applying a copper layer on the seed layer via electroplating.

In the tapered vias disclosed herein, the smaller diameter side of the tapered through-hole may be filled (e.g., plugged) with copper near the beginning of the copper electroplating process, thereby resulting in the copper growth during the remainder of the electroplating process proceeding in one direction within the tapered through-hole from the smaller diameter side to the larger diameter side. With the copper growth proceeding in one direction, seam void defects that can be observed in cylindrical shaped vias may be reduced in the tapered vias disclosed herein. In addition to the reduction of seam void defects, one-directional copper growth in the electroplating process enables the copper filling rate (e.g., the ratio of electroplated volume to overall via volume) to be easily controlled. Further, by using a tapered through-hole, plugging of a polymer or electrically conductive material into the partially filled via after the electroplating process is a one-step process rather than a two-step process, since the plugging is completed from the larger diameter side of the tapered through-hole rather than from both sides of the through-hole as is the case for cylindrical vias. In addition, from the larger via diameter surface of the substrate, the adhesion layer and the seed layer may be formed further within the through-hole than for a cylindrical shaped via, thereby improving the adhesion between the substrate and the electroplated copper.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary and are intended to provide an overview or framework to understanding the nature and character of the claims. The accompanying drawings are included to provide a further understanding and are incorporated in and constitute a part of this specification. The drawings illustrate one or more embodiment(s), and together with the description explain principles and operation of the various embodiments.

### BRIEF DESCRIPTION OF THE DRAWINGS

FIGS. 1A-1F are cross-sectional views of exemplary vias;

FIGS. 2A-2D are cross-sectional views illustrating an exemplary process for fabricating a via; and

FIGS. 3A and 3B are flow diagrams illustrating an exemplary method for fabricating a via.

### DETAILED DESCRIPTION

Reference will now be made in detail to embodiments of the present disclosure, examples of which are illustrated in the accompanying drawings. Whenever possible, the same reference numerals will be used throughout the drawings to refer to the same or like parts. However, this disclosure may be embodied in many different forms and should not be construed as limited to the embodiments set forth herein.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein-for example up, down, right, left, front, back, top, bottom, vertical, horizontal-are made only with reference to the figures as drawn and are not intended to imply absolute orientation.

Unless otherwise expressly stated, it is in no way intended that any method set forth herein be construed as requiring that its steps be performed in a specific order, nor that with any apparatus, specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an,” and “the” include plural references unless the context clearly dictates otherwise. Thus, for example, reference to “a” component includes aspects having two or more such components, unless the context clearly indicates otherwise.

Micro light-emitting diode (microLED) display applications have received interest due to their higher brightness, higher illuminance, and longer lifetime compared to other display applications. For tiled microLED displays, an electrical interconnect may connect a microLED on one surface of a backplane to integrated circuit (IC) drivers on a backside of the backplane. While there are different technologies for achieving these interconnects, the use of metallized through-glass vias (TGVs) as the electrical interconnect for glass based backplanes may offer improved electrical performance compared to other alternatives. Therefore, the use of metallized TGVs in microLED displays may be desirable. Use of metallized TGVs may also be desired for other display and non-display applications, such as liquid crystal displays, organic light-emitting diode (OLED) displays, photovoltaic devices, interposers, micro electro-mechanical systems (MEMS), and other devices and applications where interconnection between the substrate top and bottom surfaces is desired.

The high temperature processing requirements of thin-film transistor (TFT) active matrix backplanes utilized in microLED and other display technologies, however, leads to a large thermal expansion mismatch between the metallized TGV and the glass substrate, resulting in the buildup of stresses which may lead to the formation of cracks that may result in product failure. The TGVs may be metallized using electroplating processes. Electroplating however, typically proceeds under low electric current densities to prevent seam void defects resulting in longer electroplating process times.

To mitigate against the aforementioned drawbacks, disclosed herein are tapered vias where metallization proceeds from the smaller diameter side of the via to the larger diameter side of the via. This increases the reliability of the vias, reduces the electroplating process times, and reduces the cost of the electroplating process. The copper filling rate (i.e., the ratio of electroplated copper volume to overall via volume) may be controlled. In addition, depending on post via fabrication processes (e.g., thin-film transistor fabrication, redistribution layer fabrication, etc.), metallization processes with multiple copper filling rates may be used by varying the electroplating process conditions such as the electric current density and the applying pattern.

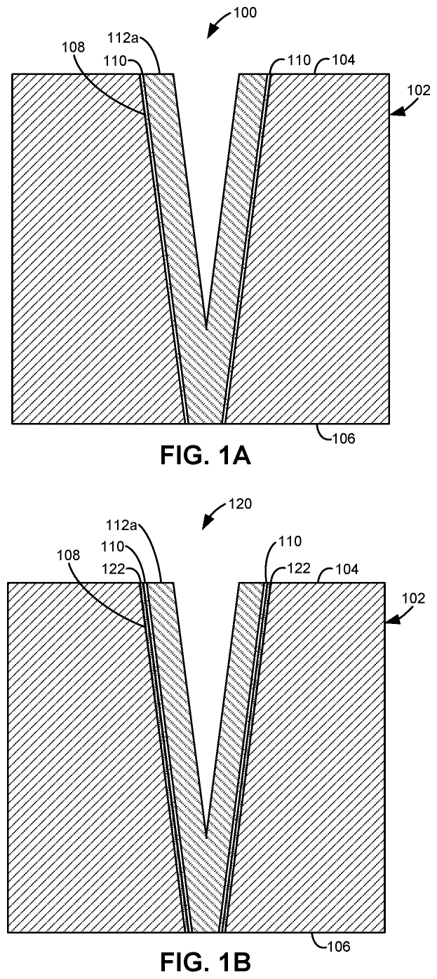

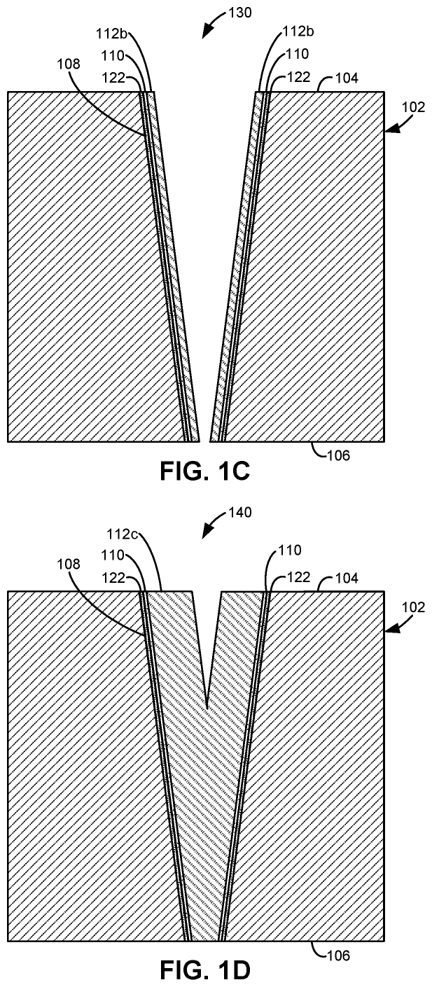

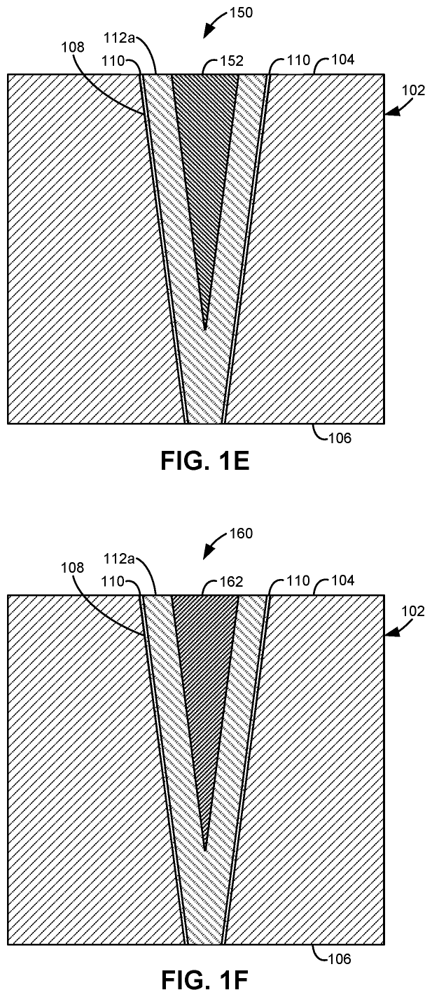

Referring now to FIG. 1A, a cross-sectional view of an exemplary via 100 is depicted. Via 100 includes a substrate 102, a seed layer 110, and an electroplated layer 112a. The substrate 102 includes a first surface 104 and a second surface 106 opposite to the first surface 104. The substrate 102 includes a tapered through-hole 108 extending from the first surface 104 to the second surface 106. In certain exemplary embodiments, the substrate 102 may be a silicon substrate. In other embodiments, the substrate 102 may be a non-silicon substrate, such as a glass substrate, a ceramic substrate, or a glass-ceramic substrate. In yet other embodiments, the substrate 102 may include Alumina, AlN, Quartz (Sapphire), InGaN, GaAs, InGaAs, GaP, GaSb, InP, InAs, InSb, GaN on Sapphire, SOI, SIMOX, Ge, crystal aluminum oxide (Garnet), or another suitable material or combination thereof. The tapered through-hole 108 includes a first diameter proximate (e.g., aligned with) the first surface 104 and a second diameter less than the first diameter proximate (e.g., aligned with) the second surface 106. In certain exemplary embodiments, the first diameter is within a range between about 80 micrometers and about 160 micrometers, and the second diameter is within a range between about 10 micrometers and about 25 micrometers. The diameter of the through-hole 108 may gradually decrease from the first surface 104 to the second surface 106. The through-hole 108 taper may be linear or non-linear in shape.

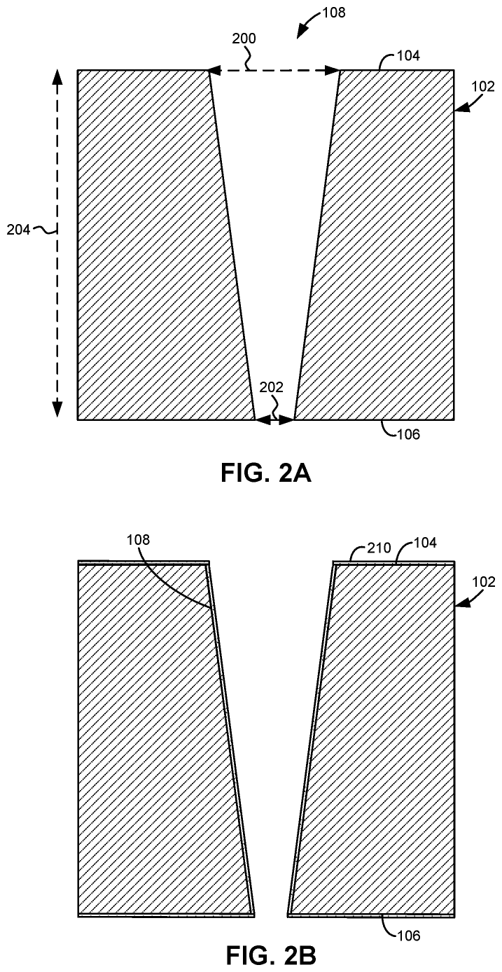

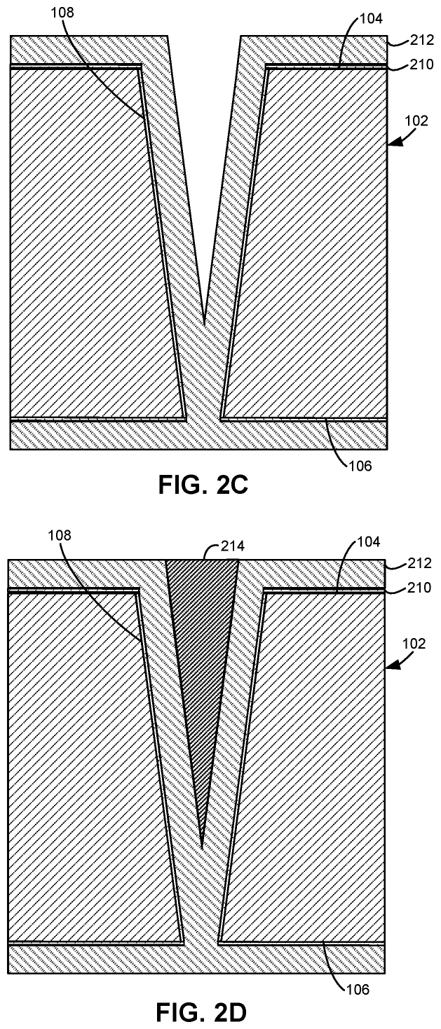

The seed layer 110 may include copper or another suitable material. The seed layer 110 contacts (e.g., directly contacts) the substrate 102 on sidewalls of the tapered through-hole 108. In certain exemplary embodiments, the seed layer 110 may include a thickness (e.g, measured in a direction perpendicular to the sidewalls of the tapered through-hole 108) within a range between about 0.2 micrometers and about 2.0 micrometers. The electroplated layer 112a may include copper or another suitable material. The electroplated layer 112a contacts (e.g., directly contacts) the seed layer 110 and partially fills the through-hole 108. The electroplated layer 112a plugs the through-hole 108 proximate the second surface 106. The volume of the electroplated layer 112a within the tapered through-hole 108 may be controlled by controlling the electroplating process as will be described in more detail below with reference to FIG. 2C. In this embodiment, the electroplated layer 112a may fill between about 30 percent and about 60 percent of the volume of the through-hole 108.

FIG. 1B is a cross-sectional view of another exemplary via 120. Via 120 is similar to via 100 previously described and illustrated with reference to FIG. 1A, except that via 120 includes an adhesion layer 122 between the substrate 102 and the seed layer 110. The adhesion layer 122 may include metallic titanium and/or titanium oxide and/or another suitable material. The adhesion layer 122 contacts (e.g., directly contacts) the substrate 102 on sidewalls of the tapered through-hole 108. In certain exemplary embodiments, the adhesion layer 122 may include a thickness (e.g., measured in a direction perpendicular to the sidewalls of the tapered through-hole 108) within a range between about 0.02 micrometers and about 0.2 micrometers.

FIG. 1C is a cross-sectional view of another exemplary via 130. Via 130 is similar to via 120 previously described and illustrated with reference to FIG. 1B, except that via 130 includes an electroplated layer 112b having a different thickness. In this embodiment, the thickness of the electroplated layer 112b is less than the thickness of the electroplated layer 112a of the via 120. In this case, the electroplated layer 112b does not plug the through-hole 108 proximate the second surface 106. In this embodiment, the electroplating process may be controlled such that the electroplated layer 112b may fill between about 5 percent and about 30 percent of the volume of the through-hole 108.

FIG. 1D is a cross-sectional view of another exemplary via 140. Via 140 is similar to via 120 previously described and illustrated with reference to FIG. 1B, except that via 140 includes an electroplated layer 112c having a different thickness. In this embodiment, the thickness of the electroplated layer 112c is greater than the thickness of the electroplated layer 112a of the via 120. In this embodiment, the electroplating process may be controlled such that the electroplated layer 112c may fill between about 60 percent and about 95 percent of the volume of the through-hole 108.

FIG. 1E is a cross-sectional view of another exemplary via 150. Via 150 is similar to via 100 previously described and illustrated with reference to FIG. 1A, except that via 150 includes an electrically conductive material (e.g., metal) 152 contacting the electroplated layer 112a and filling the through-hole 108. In other embodiments, via 150 may further include an adhesion layer 122 between the substrate 102 and the seed layer 110 as previously described and illustrated with reference to FIG. 1B. While via 150 includes electroplated layer 112a, in other embodiments, via 150 may include an electroplated layer having another suitable thickness, such as electroplated layer 112b of FIG. 1C or electroplated layer 112c of FIG. 1D.

The first surface 104 of the substrate 102 and the exposed surfaces of seed layer 110, electroplated layer 112a, and electrically conductive material 152 aligned with the first surface 104 are compatible with the fabrication of a redistribution layer and/or thin-film devices (e.g, thin-film transistors) directly on the surfaces. Likewise, the second surface 106 of the substrate 102 and the exposed surfaces of seed layer 110 and the electroplated layer 112a aligned with the second surface 106 are also compatible with the fabrication of a redistribution layer and/or thin-film devices directly on the surfaces.

FIG. 1F is a cross-sectional view of another exemplary via 160. Via 160 is similar to via 100 previously described and illustrated with reference to FIG. 1A, except that via 160 includes a polymer 162 contacting the electroplated layer 112a and filling the through-hole 108. In certain exemplary embodiments, the polymer 162 includes a sol-gel. In other embodiments, via 160 may further include an adhesion layer 122 between the substrate 102 and the seed layer 110 as previously described and illustrated with reference to FIG. 1B. While via 160 includes electroplated layer 112a, in other embodiments, via 160 may include an electroplated layer having another suitable thickness, such as electroplated layer 112b of FIG. 1C or electroplated layer 112c of FIG. 1D.

The first surface 104 of the substrate 102 and the exposed surfaces of seed layer 110, electroplated layer 112a, and polymer 162 aligned with the first surface 104 are compatible with the fabrication of a redistribution layer and/or thin-film devices (e.g., thin-film transistors) directly on the surfaces. Likewise, the second surface 106 of the substrate 102 and the exposed surfaces of seed layer 110 and the electroplated layer 112a aligned with the second surface 106 are also compatible with the fabrication of a redistribution layer and/or thin-film devices directly on the surfaces.

FIGS. 2A-2D are cross-sectional views illustrating an exemplary process for fabricating a via, such as via 100 of FIG. 1A, via 120 of FIG. 1B, via 130 of FIG. 1C, via 140 of FIG. 1D, via 150 of FIG. 1E, or via 160 of FIG. 1F. As illustrated in FIG. 2A, a tapered through-hole 108 is first formed through a substrate 102. The tapered through-hole 108 includes a first diameter as indicated at 200 proximate (e.g., aligned with) the first surface 104 and a second diameter as indicated at 202 less than the first diameter 200 proximate (e.g., aligned with) the second surface 106. In certain exemplary embodiments, the first diameter 200 is within a range between about 80 micrometers and about 160 micrometers, and the second diameter 202 is within a range between about 10 micrometers and about 25 micrometers. The substrate 102 may have a thickness as indicated at 204, for example, within a range between about 200 micrometers and about 400 micrometers.

In certain exemplary embodiments, the tapered through-hole 108 may be formed by laser damaging the substrate and etching the damaged portions of the substrate. In other embodiments, tapered through-hole 108 may be formed by photolithography and etching processes, drilling processes (e.g., laser drilling), and/or other suitable processes. Depending on the substrate material, utilized etching processes may be wet etchant, vapor etchant, plasma etchant, or other.

FIG. 2B is a cross-sectional view of the tapered through-hole 108 of FIG. 2A after depositing an adhesion layer and/or a seed layer 210 on the substrate 102. The adhesion and/or seed layer 210 may be applied onto the first surface 104, the second surface 106 and the sidewalls of the tapered through-hole 108 via sputtering or another suitable process. In certain exemplary embodiments, an adhesion layer may first be deposited onto the substrate 102 to a thickness within a range between about 0.02 micrometers and about 0.2 micrometers followed by a seed layer deposited onto the adhesion layer to a thickness within a range between about 0.2 micrometers and about 2.0 micrometers. In some embodiments, a first (e.g., base portion) of the seed layer is deposited via sputtering and a second (e.g., top portion) of the seed layer is deposited via electroless plating to obtain the desired thickness of the seed layer.

FIG. 2C is a cross-sectional view of the tapered through-hole 108 of FIG. 2B after electroplating a copper layer 212 on the adhesion layer and/or the seed layer 210. The copper plugs the smaller diameter side of the tapered through-hole 108 towards the beginning of the electroplating process such that the copper growth during the remainder of the electroplating process proceeds in one direction within the tapered through-hole 108 from the smaller diameter side to the larger diameter side. In this way, seam void defects are reduced and the electroplating process can be further controlled to control the copper filling rate. For example, the electroplating process may include a pulsed electric current density to vary the thickness of the copper layer 212 along the sidewalls of the tapered through-hole 108. In other examples, the electroplating process may include a constant electric current density to apply a conformal copper layer 212 on the sidewalls of the tapered through-hole 108.

FIG. 2D is a cross-sectional view of the tapered through-hole 108 of FIG. 2C after filling the remaining open portion of the tapered through-hole 108 with an electrically conductive material (e.g., metal) or a polymer (e.g., sol-gel) 214. The remaining open portion of the tapered through-hole 108 is filled from the first surface 104 of the substrate 102 and not from the second surface 106. Accordingly, the filling process for tapered through-hole 108 is simplified compared to the filling process for cylindrical vias, which may be filled from both the first surface and the second surface of the substrate. After filling the through-hole 108, the resulting structure may be planarized using chemical-mechanical polishing or another suitable process to expose the first surface 104 and the second surface 106 to form the via 150 of FIG. 1E or the via 160 of FIG. 1F.

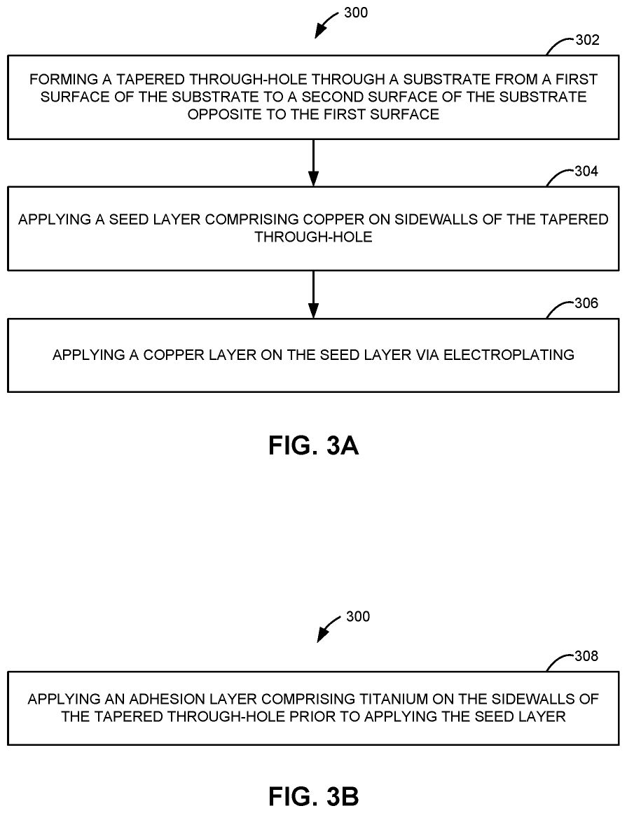

FIGS. 3A and 3B are flow diagrams illustrating an exemplary method 300 for fabricating a via, such as via 100 of FIG. 1A, via 120 of FIG. 1B, via 130 of FIG. 1C, via 140 of FIG. 1D, via 150 of FIG. 1E, or via 160 of FIG. 1F. As illustrated in FIG. 3A at 302, method 300 may include forming a tapered through-hole (e.g., 108 of FIG. 2A) through a substrate (e.g., 102) from a first surface (e.g., 104) of the substrate to a second surface (e.g., 106) of the substrate opposite to the first surface. In certain exemplary embodiments, forming the tapered through-hole includes laser damaging the substrate and etching the damaged portions of the substrate. At 304, method 300 may include applying a seed layer (e.g., 210 of FIG. 2B) comprising copper on sidewalls of the tapered through-hole. In certain exemplary embodiments, applying the seed layer may include forming a first portion of the seed layer via sputtering and a second portion of the seed layer via electroless plating. At 306, method 300 may include applying a copper layer (e.g., 212 of FIG. 2C) on the seed layer via electroplating In certain exemplary embodiments, the electroplating may include a pulsed electric current density to vary a thickness of the copper layer along the sidewalls of the tapered through-hole. In other embodiments, the electroplating may include a constant electric current density to apply a conformal copper layer on the sidewalls of the tapered through-hole.

As illustrated in FIG. 3B at 308, method 300 may further include applying an adhesion layer (e.g., 122 of FIG. 1B) comprising titanium on the sidewalls of the tapered through-hole prior to applying the seed layer. In certain exemplary embodiments, method 300 may further include filling the tapered through-hole with an electrically conductive material (e.g., 152 of FIG. 1E) or a polymer (e.g., 162 of FIG. 1F) and chemical-mechanical polishing to expose the first surface and the second surface of the substrate proximate the tapered through-hole (e.g., to form via 150 of FIG. 1E or 160 of FIG. 1F).

It will be apparent to those skilled in the art that various modifications and variations can be made to embodiments of the present disclosure without departing from the spirit and scope of the disclosure. Thus, itis intended that the present disclosure cover such modifications and variations provided they come within the scope of the appended claims and their equivalents.

What is claimed is:

1. A via comprising:
a substrate comprising a first surface and a second surface opposite to the first surface, the substrate comprising a tapered through-hole extending from the first surface to the second surface;
a seed layer comprising copper contacting the substrate on sidewalls of the tapered through-hole; and
an electroplated layer comprising copper contacting the seed layer.

2. The via of claim 1, wherein the tapered through-hole comprises a first diameter proximate the first surface and a second diameter less than the first diameter proximate the second surface, and
wherein the electroplated layer plugs the through-hole proximate the second surface.

3. The via of claim 2, wherein the first diameter is within a range between about 80 micrometers and about 160 micrometers, and
wherein the second diameter is within a range between about 10 micrometers and about 25 micrometers.

4. The via of claim 1, wherein the seed layer comprises a thickness within a range between about 0.2 micrometers and about 2.0 micrometers.

5. The via of claim 1, wherein the substrate comprises a glass, a glass-ceramic, or a ceramic.

6. The via of claim 1, further comprising:
an electrically conductive material contacting the electroplated layer and filling the through-hole.

7. The via of claim 1, further comprising:
an adhesion layer comprising metallic titanium and titanium oxide between the substrate and the seed layer.

8. The via of claim 7, wherein the adhesion layer comprises a thickness within a range between about 0.02 micrometers and about 0.2 micrometers.

9. A via comprising:
a substrate comprising a first surface and a second surface opposite to the first surface, the substrate comprising a tapered through-hole extending from the first surface to the second surface;
a seed layer comprising copper contacting the substrate on sidewalls of the tapered through-hole;
an electroplated layer comprising copper contacting the seed layer; and
a polymer contacting the electroplated layer and filling the through-hole.

10. The via of claim 9, wherein the polymer includes a sol-gel.

11. The via of claim 9, wherein the tapered through-hole comprises a first diameter proximate the first surface and a second diameter less than the first diameter proximate the second surface, and
wherein the electroplated layer plugs the through-hole proximate the second surface.

12. The via of claim 11, wherein the first diameter is within a range between about 80 micrometers and about 160 micrometers, and
wherein the second diameter is within a range between about 10 micrometers and about 25 micrometers.

13. The via of claim 9, wherein the seed layer comprises a thickness within a range between about 0.2 micrometers and about 2.0 micrometers.

14. The via of claim 9, wherein the substrate comprises a glass, a glass-ceramic, or a ceramic.

15. A method for fabricating a via, the method comprising:
forming a tapered through-hole through a substrate from a first surface of the substrate to a second surface of the substrate opposite to the first surface;
applying a seed layer comprising copper on sidewalls of the tapered through-hole; and
applying a copper layer on the seed layer via electroplating.

16. The method of claim 15, wherein forming the tapered through-hole comprises laser damaging the substrate and etching the damaged portions of the substrate.

17. The method of claim 15, wherein the electroplating comprises a pulsed electric current density to vary a thickness of the copper layer along the sidewalls of the tapered through-hole.

18. The method of claim 15, wherein the electroplating comprises a constant electric current density to apply a conformal copper layer on the sidewalls of the tapered through-hole.

19. The method of claim 15, wherein applying the seed layer comprises forming a first portion of the seed layer via sputtering and a second portion of the seed layer via electroless plating.

20. The method of claim 15, further comprising:
applying an adhesion layer comprising titanium on the sidewalls of the tapered through-hole prior to applying the seed layer.
